(19) United States
(12) Patent Application Publication
(10) Pub. No.: US 2026/0324463 A1
(43) Pub. Date: Oct. 15, 2026

(54) MOUNTING BOARD

(71) Applicant: Kabushiki Kaisha Toshiba, Kawasaki-shi (JP)

(72) Inventors: Tetsuya Yamamoto, Sagamihara Kanagawa (JP); Katsuya Sato, Yokohama Kanagawa (JP)

(21) Appl. No.: 19/463,671

(22) Filed: Jan. 29, 2026

(30) Foreign Application Priority Data
Mar. 21, 2025 (JP) 2025-047477

(51) Int. Cl. H10W 70/63; H10W 72/90

(52) U.S. Cl. CPC H10W 70/635; H10W 72/931

(57) ABSTRACT

According to one embodiment, a mounting board includes a substrate, a pad, a first through hole, a resist, a solder, and a semiconductor device. The pad is provided on the substrate. The first through hole is provided within a region of the pad. The resist is provided outside the region of the pad. The solder is provided on the pad. The semiconductor device is provided on the solder. The semiconductor device includes an electrode. An area of the pad is larger than an area of the electrode. The resist includes a protruding portion protruding to the electrode.

### CROSS-REFERENCE TO RELATED APPLICATIONS

This application is based upon and claims the benefit of priority from Japanese Patent Application No. 2025-047477, filed on Mar. 21, 2025; the entire contents of which are incorporated herein by reference.

### FIELD

Embodiments described herein relate generally to a mounting board.

### BACKGROUND

For example, it is desirable for a mounting board on which a semiconductor device is mounted to suppress a position shift of the semiconductor device upon mounting.

### BRIEF DESCRIPTION OF THE DRAWINGS

FIG. 1 is a schematic plan view illustrating a mounting board according to an embodiment;

FIG. 2 is a schematic cross-sectional view illustrating the mounting board according to the embodiment;

FIG. 3 is a schematic plan view illustrating the mounting board according to the embodiment;

FIG. 4 is a schematic plan view illustrating the mounting board according to the embodiment; and

FIG. 5 is a schematic plan view illustrating the mounting board according to the embodiment.

### DETAILED DESCRIPTION

According to one embodiment, a mounting board includes a substrate, a pad, a first through hole, a resist, a solder, and a semiconductor device. The pad is provided on the substrate. The first through hole is provided within a region of the pad. The resist is provided outside the region of the pad. The solder is provided on the pad. The semiconductor device is provided on the solder. The semiconductor device includes an electrode. An area of the pad is larger than an area of the electrode. The resist includes a protruding portion protruding to the electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

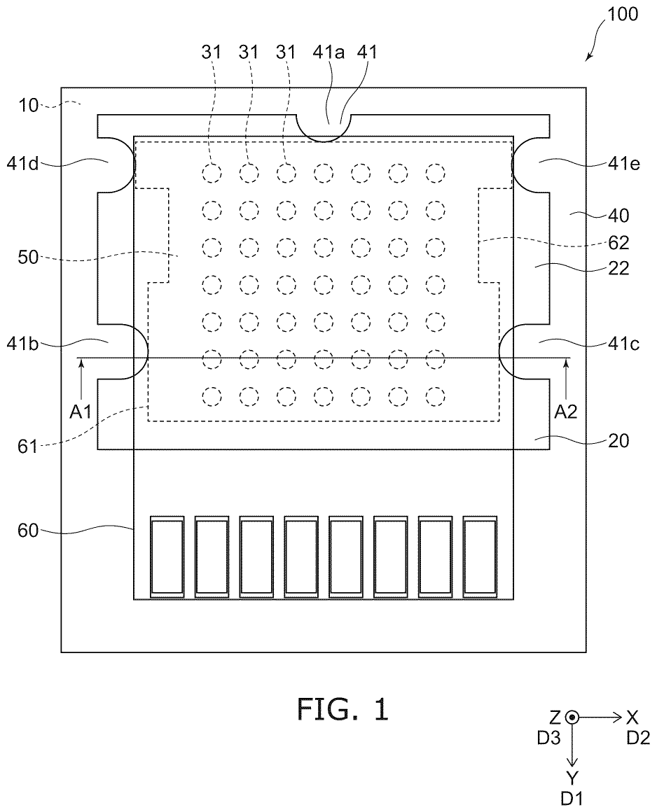

FIG. 1 is a schematic plan view illustrating a mounting board according to an embodiment.

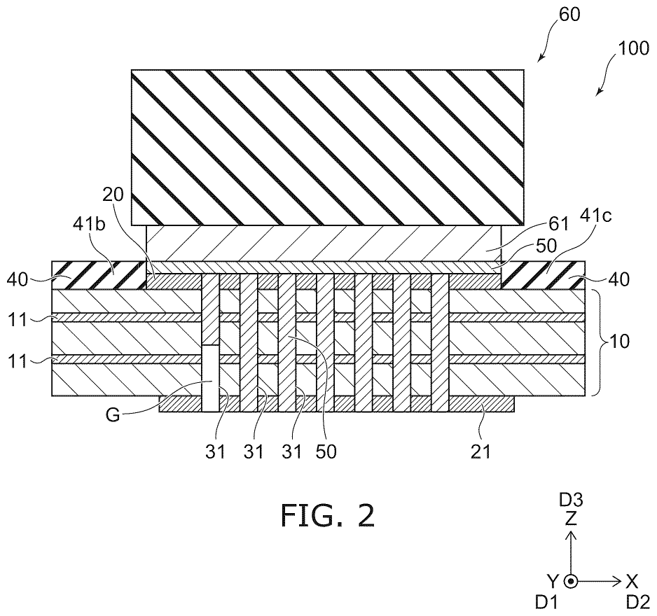

FIG. 2 is a schematic cross-sectional view illustrating the mounting board according to the embodiment. FIG. 2 is a cross-sectional view taken along line A1-A2 of FIG. 1.

As shown in FIG. 1 and FIG. 2, a mounting board 100 includes a substrate 10, a pad 20, a first through hole 31, a resist 40, a solder 50, and a semiconductor device 60.

In the following description, the direction from the substrate 10 toward the semiconductor device 60 is referred to as “on”, and the direction from the semiconductor device 60 toward the substrate 10 is referred to as “under”.

As shown in FIG. 1, the first through hole 31 is provided within the region of the pad 20. The resist 40 is provided outside the region of the pad 20. In plan view, the pad 20 is surrounded by the resist 40.

As shown in FIG. 2, the pad 20 is provided on the substrate 10. The solder 50 is provided on the pad 20. The pad 20 and the first through hole 31 are connected to an electrode 61 via the solder 50. The solder 50 is mainly used to mount the semiconductor device 60.

The semiconductor device 60 is provided on the solder 50. The semiconductor device 60 includes the electrode 61. The electrode 61 may be a back electrode of the semiconductor device 60. The back electrode may be the drain electrode of the semiconductor device 60.

As shown in FIG. 1, the region of the pad 20 includes the region of the electrode 61. The region of the electrode 61 and the region between the electrode 61 and the resist 40 shown in FIG. 1 correspond to the region of the pad 20. In the mounting board 100, the area of the pad 20 is larger than the area of the electrode 61. In plan view, the resist 40 includes a protruding portion 41 protruding to the electrode 61.

A first reference example is possible in which the area of the pad 20 is larger than the area of the electrode 61, and the resist 40 does not include the protruding portion 41 protruding to the electrode 61. Since the first through hole 31 is provided in the pad 20 facing the electrode 61 in order to improve the heat dissipation performance, the solder 50 wets and spreads toward the first through hole 31 in the first reference example, and the amount of solder is decreased accordingly. Therefore, a fillet to be formed with the semiconductor device 60 is not formed, resulting in a lack of strength and a decrease in reliability. It is possible to make the area of the pad 20 larger than the area of the electrode 61 and increase the amount of solder, however, if the amount of solder is large, the semiconductor device 60 is likely to float and move when the solder 50 is melted, and a position shift may occur. A second reference example is possible in which the area of the pad 20 is the same as the area of the electrode 61. In the second reference example, a void may be generated between the pad 20 and the electrode 61.

In the mounting board 100 according to the embodiment, even if the amount of solder is increased, the semiconductor device 60 can be positioned by the protruding portion 41 of the resist 40. Therefore, a position shift of the semiconductor device 60 can be suppressed. Since the area of the pad 20 is larger than the area of the electrode 61, generation of solder balls can be suppressed.

The first through hole 31 includes a plurality of first through holes 31. The plurality of first through holes 31 are arranged in a first direction D1 and in a second direction D2 crossing the first direction D1.

The first direction D1 may be, for example, a Y-axis direction. One direction perpendicular to the Y-axis direction is taken as an X-axis direction. A direction perpendicular to the X-axis direction and the Y-axis direction is taken as a Z-axis direction. The second direction D2 crossing the first direction D1 may be, for example, the X-axis direction.

The substrate 10 may be, for example, an epoxy substrate, a glass epoxy substrate, or a flexible substrate. The thickness of the substrate 10 may be, for example, 0.8 mm or more and 3.2 mm or less.

The pad 20 may include, for example, copper, silver, gold, or an alloy thereof. The thickness of the pad 20 may be, for example, 0.0125 mm or more and 0.1 mm or less. The pad 20 may be formed by plating.

The diameter of the first through hole 31 may be, for example, 0.1 mm or more and 1.0 mm or less. The first through hole 31 may extend through the substrate 10 and the pad 20.

The first through hole 31 need not be filled with a resin. The first through hole 31 need not be filled by plating. The inside of the first through hole 31 may have a plating film on the wall surface of the first through hole 31.

The resist 40 may be formed by photoresist or screen printing.

The mounting board 100 may include a backside pad 21 provided under the substrate 10. Including the backside pad 21 facilitates heat dissipation of the semiconductor device 60. The heat dissipation performance of the mounting board 100 is improved.

The semiconductor device 60 is mounted on the pad 20 by applying a solder paste and performing reflow. The thickness of the solder paste is about 0.08 mm or more and 0.16 mm or less. The thickness of the solder 50 may be, for example, 0.04 mm or more and 0.08 mm or less. The thickness of the solder 50 is a thickness after the mounting (after the reflow).

The semiconductor device 60 may be, for example, an FET (Field Effect Transistor). In the FET, the current flows at a high voltage. Therefore, heat is likely to be generated. In the mounting board 100, the void described above is discharged through the first through hole 31, which facilitates heat dissipation of the semiconductor device 60. The heat dissipation performance of the mounting board 100 is improved.

The area of the pad 20 may be, for example, 40 mm² or more and 80 mm² or less. The area of the electrode 61 may be, for example, 32 mm² or more and 64 mm² or less.

As shown in FIG. 1, the electrode 61 may include a recessed portion 62. The pad 20 may include a print extension region 22 in which the solder 50 is printed. The print extension region 22 may be present between the recessed portion 62 and the resist 40. Since the print extension region 22 is present, generation of solder balls can be suppressed.

The protruding portion 41 may have, for example, a semicircular shape, an elliptical shape, or a rectangular shape.

As shown in FIG. 2, the solder 50 may be present in at least a part of the inside of the first through hole 31. A gap G may be present in the inside of the first through hole 31. The solder 50 may be present in the entire inside of the first through hole 31. These configurations allow transient heat generated from the semiconductor device 60 to be absorbed by the solder 50 inside the first through hole 31, which facilitates heat dissipation of the semiconductor device 60. As a result, the heat dissipation performance of the mounting board 100 is improved. The size of the heat sink can be reduced.

As shown in FIG. 1, the protruding portion 41 may include a first protruding portion 41a, a second protruding portion 41b, and a third protruding portion 41c. The first protruding portion 41a protrudes in the first direction D1. The second protruding portion 41b protrudes in the second direction D2 crossing the first direction D1. The second protruding portion 41b and the third protruding portion 41c protrude in opposite directions.

In the mounting board 100, since the protruding portion 41 includes the first protruding portion 41a, the second protruding portion 41b, and the third protruding portion 41c, a position shift of the semiconductor device 60 can be further suppressed.

The protruding portion 41 may further include a fourth protruding portion 41d and a fifth protruding portion 41e. The fourth protruding portion 41d is arranged side by side with the second protruding portion 41b in the first direction D1. The fifth protruding portion 41e is arranged side by side with the third protruding portion 41c in the first direction D1. The fourth protruding portion 41d protrudes in the second direction D2. The fourth protruding portion 41d and the fifth protruding portion 41e protrude in opposite directions. This can further suppress a position shift of the semiconductor device 60.

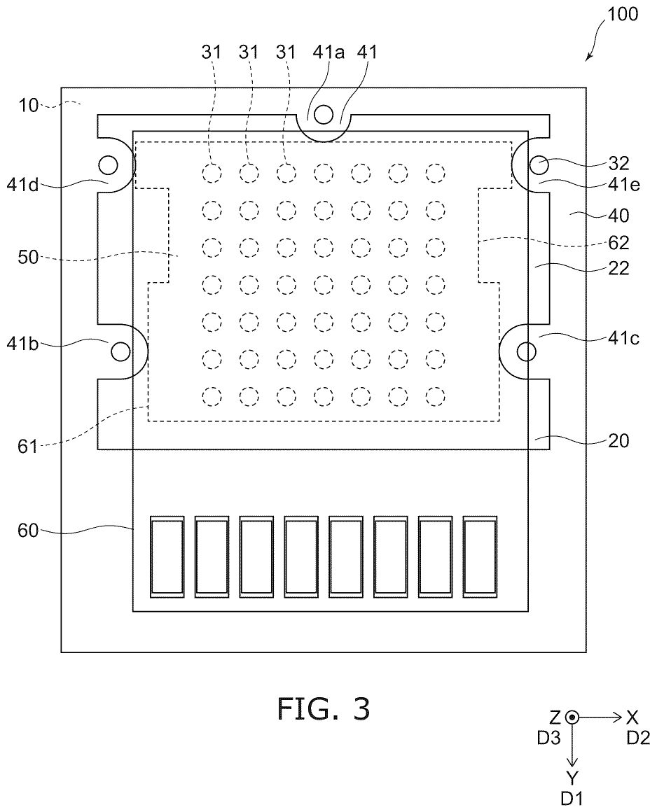

FIG. 3 is a schematic plan view illustrating the mounting board according to the embodiment.

As shown in FIG. 3, the mounting board 100 may further include a second through hole 32 provided in the protruding portion 41. The second through hole 32 is connected to the first through hole 31 via a wiring 11 inside the substrate 10. This further allows heat dissipation of the semiconductor device 60 without affecting drawing of the solder 50 by the first through hole 31. As a result, the heat dissipation performance of the mounting board 100 is improved.

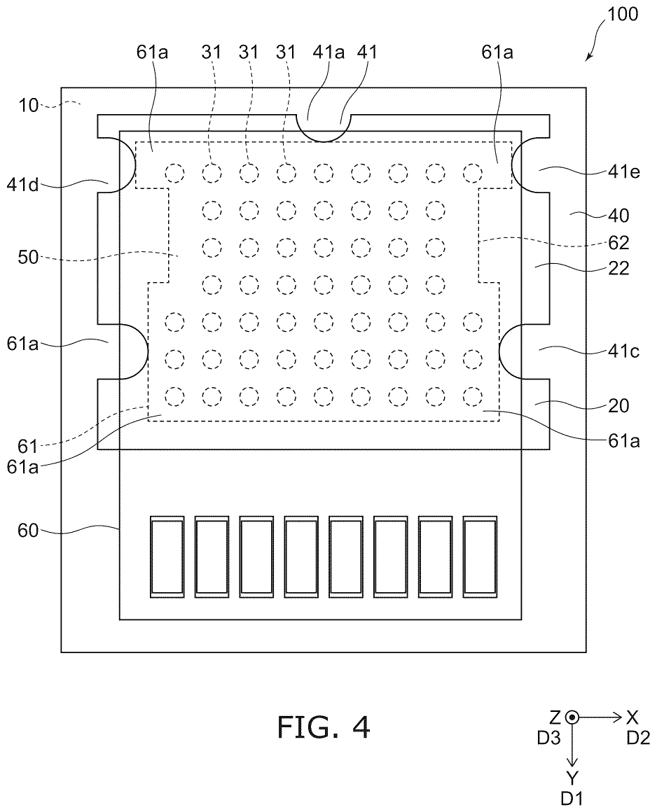

FIG. 4 is a schematic plan view illustrating the mounting board according to the embodiment.

As shown in FIG. 4, the first through hole 31 may be provided at a position of the pad 20 corresponding to the position of an end portion 61a of the electrode 61. This allows a larger number of the first through holes 31 to be provided within the region of the pad 20. As a result, the heat dissipation performance of the mounting board 100 is improved.

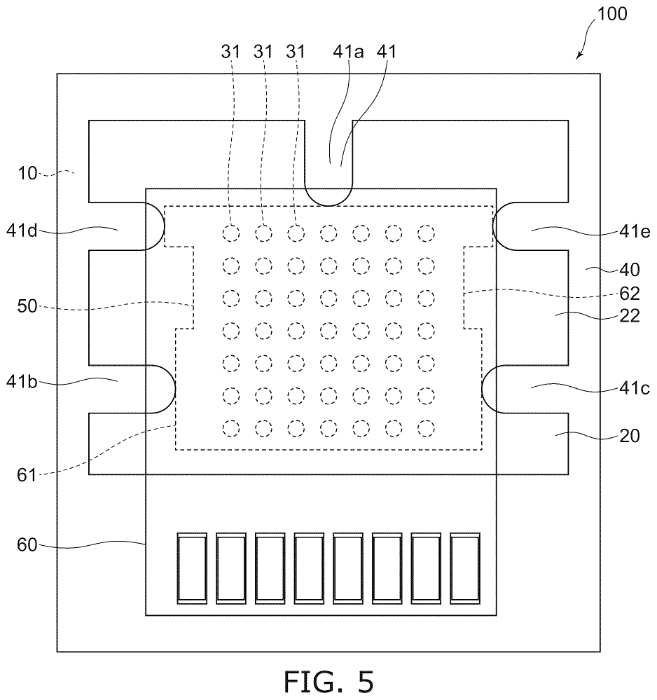

FIG. 5 is a schematic plan view illustrating the mounting board according to the embodiment.

As shown in FIG. 5, the print extension region 22 can be extended toward the resist 40. In a case where no adjacent electronic components are present around the pad 20, the area of the print extension region 22 can be extended up to 143.7 mm². The area of the print extension region 22 may be less than 143.7 mm².

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the mounting boards such as the substrate, pad, through holes, resist, solder, semiconductor device, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all mounting boards practicable by an appropriate design modification by one skilled in the art based on the mounting boards described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A mounting board comprising:
a substrate;
a pad provided on the substrate;
a first through hole provided within a region of the pad;
a resist provided outside the region of the pad;
a solder provided on the pad; and
a semiconductor device provided on the solder and including an electrode,
an area of the pad being larger than an area of the electrode,
the resist including a protruding portion protruding to the electrode.

2. The mounting board according to claim 1, wherein
the electrode includes a recessed portion,
the pad includes a print extension region in which the solder is printed, and
the print extension region is present between the recessed portion and the resist.

3. The mounting board according to claim 1, further comprising:
a second through hole provided in the protruding portion.

4. The mounting board according to claim 1, wherein the solder is present in at least a part of an inside of the first through hole.

5. The mounting board according to claim 1, wherein the solder is present in an entire inside of the first through hole.

6. The mounting board according to claim 1, wherein
the protruding portion includes a first protruding portion, a second protruding portion, and a third protruding portion,
the first protruding portion protrudes in a first direction,
the second protruding portion protrudes in a second direction crossing the first direction, and
the second protruding portion and the third protruding portion protrude in opposite directions.

7. The mounting board according to claim 1, wherein the semiconductor device is an FET.
